(19) United States
(12) Patent Application Publication
(10) Pub. No.: US 2005/0061997 A1
(43) Pub. Date: Mar. 24, 2005

(54) Ion beam slit extraction with mass separation

(76) Inventor: Victor M. Benveniste, Gloucester, MA (US)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 10/669,186

(22) Filed: Sep. 24, 2003

(51) Int. Cl. H01J 37/317; H01J 37/08

(52) U.S. Cl. 250/492.21; 250/298; 250/423 R

(57) ABSTRACT

The present invention employs a mass analyzer comprised of a pair of permanent magnets to select a desired species from multiple species within a ribbon type ion beam. These permanent magnets provide a substantially uniform magnetic field of adequate magnitude in a small region not attainable with electromagnets that applies a specific force in a desired direction. The force is applied to passing particles of a ribbon ion beam and causes paths of the particles to alter according to their respective mass. As a result, a selected species can be obtained from a beam by the force causing rejected species and/or contaminants to fail passing through the mass analyzer (e.g., by impacting the magnets themselves and/or another barrier present in the analyzer). As a result of the mass analyzer, dopant/species sources that generate multiple species can be employed instead of sources that only supply a single dopant/species.

### FIELD OF INVENTION

The present invention relates generally to ion implantation devices, and more particularly, to a ribbon ion beam system that includes mass separation.

### BACKGROUND OF THE INVENTION

Ion implantation is a physical process, as opposed to diffusion, which is a chemical process, that is employed in semiconductor device fabrication to selectively implant dopant into semiconductor and/or wafer material. Thus, the act of implanting does not rely on a chemical interaction between a dopant and the semiconductor material. For ion implantation, dopant atoms/molecules are ionized and isolated, sometimes accelerated or decelerated, formed into a beam, and swept across a wafer. The dopant ions physically bombard the wafer, enter the surface and come to rest below the surface.

An ion implantation system is a collection of sophisticated subsystems, each performing a specific action on the dopant ions. Dopant elements, in gas or solid form, are positioned inside an ionization chamber and ionized by a suitable ionization process. In one exemplary process, the chamber is maintained at a low pressure (vacuum). A filament is located within the chamber and is heated to the point where electrons are created from the filament source. The negatively charged electrons are attracted to an oppositely charged anode also within the chamber. During the travel from the filament to the anode, the electrons collide with the dopant source elements (e.g., molecules or atoms) and create a host of positively charged ions from the elements in the molecule.

Generally, other positive ions are created in addition to desired dopant ions. The desired dopant ions are selected from the ions by a process referred to as analyzing, mass analyzing, selection, or ion separation. Selection is accomplished utilizing a mass analyzer that creates a magnetic field through which ions from the ionization chamber travel. The ions leave the ionization chamber at relatively high speeds and are bent into an arc by the magnetic field. The radius of the arc is dictated by the mass of individual ions, speed, and the strength of the magnetic field. An exit of the analyzer typically permits primarily one species of ions, the desired dopant ions, to exit the mass analyzer.

An acceleration system, referred to as a linear accelerator, is employed in some instances to accelerate or decelerate the desired dopant ions to a predetermined momentum (e.g., mass of a dopant ion multiplied by its velocity) to penetrate the wafer surface. For acceleration, the system is generally of a linear design with annular powered electrodes and pairs of quadrupole lenses along its axis. The quadruple lenses are powered by negative and positive electrical potentials. As the dopant ions enter therein, they are accelerated therethrough by the powered electrodes and are (as a beam) selectively focused by the quadruple lenses. Continuing on, the dopant ions are directed towards a target wafer at an end station.

Ion implantation systems can generally be classified into one of two categories, pencil type and ribbon beam type systems. Pencil type ion implantation systems employed a pencil-type ion beam, wherein a relatively narrow beam is produced by the ion source and subjected to mass analysis, subsequent beam conditioning, and scanning before reaching the workpiece. Many present applications, however, wish to obtain shallow implants with a relatively high dopant concentration, for example, in shallow source/drain regions in semiconductor manufacturing. For shallow depth ion implantation, high current, low energy ion beams are desirable. In this case, the reduced energies of the ions cause some difficulties in maintaining convergence of the ion beam due to the mutual repulsion of ions bearing a like charge. High current ion beams typically include a high concentration of similarly charged ions that tend to diverge due to mutual repulsion. One solution to the above problem is to employ a ribbon-type ion beam instead of a pencil-type beam. One advantage of the ribbon-type beam is that the cross-sectional area of the beam is substantially larger than the pencil-type beam. For example, a typical pencil beam has a diameter of about 1-5 cm, wherein a ribbon-type beam may have a height of about 1-5 cm and a width of about 40 cm. With the substantially larger beam area, a given beam current has substantially less current density, and the beam a lower perveance. Use of a ribbon-type beam, however, has a number of unique challenges associated therewith.

Ribbon beam type systems employ an ion source that generates a slit beam. Conventional mass separation of slit beams become increasingly problematic as the length of the slit increases. The magnetic field, oriented along the direction of the slit (or ribbon) bridges a large magnetic gap between pieces of a magnet. The power required to produce such a magnetic field (about the square of the gap) is generally substantial. Consequently, some ribbon beam type systems forego the mass separator and implant all species produced by the ion source. As a consequence, the ion source is dedicated to a specific species and operates under restricted conditions with restricted feed materials so as to mitigate production of unwanted dopants. Even then, a less than ideal process can result with unwanted dopants contaminating the resultant implant.

Electromagnets are typically employed in mass analyzers as described supra. However, employing electromagnets for a mass analyzer in ribbon beam type systems require considerable cost, bulk, and complexity. As a result, utilizing electromagnets for mass separation in ribbon type ion implantation systems sometimes is not feasible.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The present invention facilitates ribbon beam ion implantation systems and operation thereof. The present invention employs a mass analyzer comprised of a pair of permanent magnets. These magnets provide a substantially uniform magnetic field that applies a specific force in a desired direction to a moving charged particle such as an ion. The force is applied to passing particles of a ribbon ion beam and causes paths of the particles to alter according to their respective mass and energy. As a result, a selected ion type can be obtained from a beam by the force causing rejected ions of undesired charge-to-mass ratios and/or contaminants to fail passing through the mass analyzer (e.g., by impacting the magnets themselves and/or another barrier present in the analyzer). In addition, by varying the extraction electrode potentials, the energy of ions entering the mass analyzer can be varied, thereby allowing permanent magnets to be used for differing dopant species. As a result of the mass analyzer, ion sources that generate multiple species (e.g., boron, phosphorous, arsenic, and the like) can be employed instead of sources that only supply a single dopant/species.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a block diagram illustrating an exemplary ion implantation system in accordance with an aspect of the present invention.

FIG. 2 is a perspective view illustrating an exemplary ion source in accordance with an aspect of the present invention.

FIG. 3 is a diagram illustrating the affect of a magnetic field on an ion beam.

FIG. 4 is a diagram illustrating a ribbon beam extraction with mass analysis system in accordance with an aspect of the present invention.

FIG. 5 is a view illustrating a mass analyzer in accordance with an aspect of the present invention.

FIG. 6 is another view illustrating a mass analyzer in accordance with an aspect of the present invention.

FIG. 7 is a flow diagram illustrating a method of generating a ribbon type ion beam in accordance with an aspect of the present invention.

FIG. 8 is a flow diagram illustrating a method of configuring a ribbon type ion beam system for a particular implant in accordance with an aspect of the present invention.

### DETAILED DESCRIPTION OF THE INVENTION

The present invention will now be described with reference to the attached drawings, wherein like reference numerals are used to refer to like elements throughout. It will be appreciated by those skilled in the art that the invention is not limited to the exemplary implementations and aspects illustrated and described hereinafter.

The present invention employs a mass analyzer comprised of a pair of permanent magnets to select a desired ion species from multiple species (e.g., ions having a desired charge-to-mass ratio for a given energy) within a ribbon type ion beam. The permanent magnets provide a substantially uniform magnetic field that applies a specific force on the ion beam in a desired direction. The force on the passing particles of the ribbon ion beam and causes paths of the particles to alter according to their respective mass. As a result, ions having a selected charge-to-mass ratio can be obtained from a beam by the force causing rejected species/ions and/or contaminants to fail passing through the mass analyzer (e.g., by impacting the magnets themselves and/or another barrier present in the analyzer). As a result of the mass analyzer, ion sources that generate multiple species (e.g., boron, phosphorous, arsenic) can be employed instead of sources that only supply a single dopant/species.

In contrast, conventional ribbon beam systems that do not employ a mass analyzer suffer from unwanted doping that may degrade device performance (often requiring that ion sources be dedicated to a specific species) and contribute to excessive heating of the substrate, ultimately limiting the throughput or productivity of the implanter. Additionally, it is difficult for conventional electromagnet based mass analyzers to provide a substantially uniform magnetic field in a small space as the mass analyzer of the present invention does, and further doing so requires a substantial amount of power.

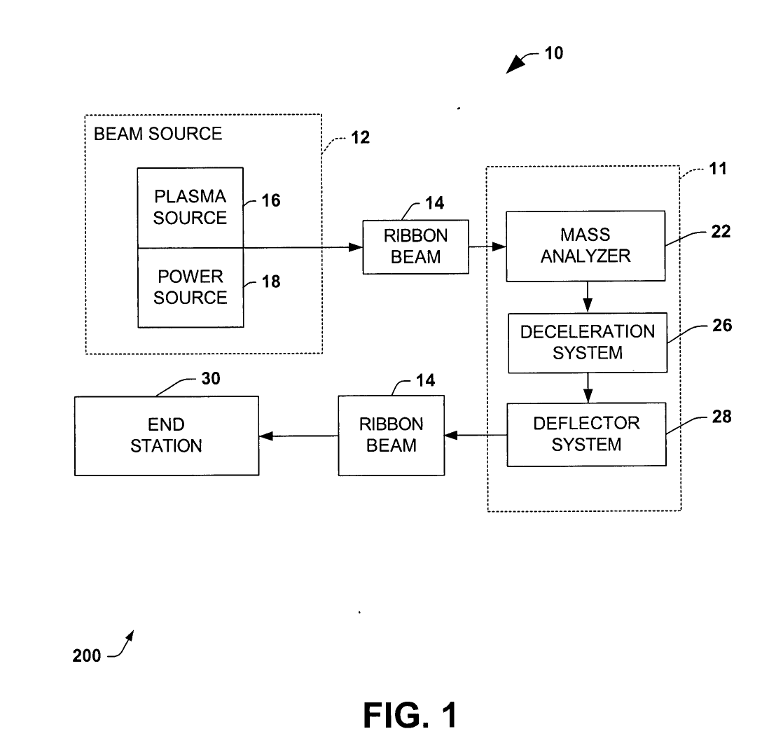

Referring initially to FIG. 1, an exemplary ion implantation system 10 in accordance with an aspect of the present invention is depicted in block diagram form. The system 10 includes an ion source 12 for producing an ion beam 14 along a beam path. The ion beam source 12 includes, for example, a plasma source 16 with an associated power source 18. The ion beam source 12 is not required to be dedicated to a particular species as are other convention ion beam sources for ribbon beam type systems. Thus, the ion beam source 12 can provide/generate a number of selectable species (e.g., boron, phosphorous, arsenic, and the like). The plasma source 16 may, for example, comprise a plasma confinement chamber from which an ion beam is extracted. The extracted beam comprises a ribbon shaped ion beam, for example, having a width of about 400 mm for implantation of a 300 mm semiconductor wafer.

A beamline assembly 11 is provided downstream of the ion source 12 to receive the ribbon beam 14 therefrom. The beamline assembly 11 includes a mass analyzer 22 and may include a deceleration system 26 and a deflector system 28. The beamline assembly 11 is situated along the path to receive the beam 14. The mass analyzer 22 includes a pair of permanent magnets that generate a uniform magnetic field across the beam path so as to deflect ions from the ion beam 14 at varying trajectories according to the charge-to-mass ratio of the respective ions. Ions traveling through the magnetic field experience a force which directs individual ions of a desired mass along the beam path and which deflects ions of undesired mass away from the beam path.

The beamline 11 may further comprise a deceleration/acceleration module 26 that is controllable and selectively operable to alter an energy associated with the ribbon beam. For example, at medium energies no substantial change in ribbon beam energy may be necessary, and the module allows the ribbon beam to pass therethrough without a substantial change thereto. Alternatively, in low energy applications (e.g., for formation of shallow junctions in a semiconductor body), the energy of the ribbon beam may need to be decelerated. In such circumstances, the deceleration module 26 is operable to reduce the energy of the beam to a desired energy level by deceleration thereof.

The beamline may further comprise a deflection system 28, for example, for use in low energy systems that employ deceleration prior to implantation into a workpiece. The deflection system 28 includes, for example, deflection electrodes for deflecting the ion beam away from the beamline axis to thereby remove neutral particles from the ribbon beam (due to their failure to deflect in the presence of a deflecting field) that may otherwise serve as energy contaminants.

An end station 30 is also provided in the system 10 to receive the mass analyzed, substantially decontaminated ion beam 14 from the beamline assembly 11. The end station 30 supports one or more workpieces such as semiconductor wafers (not shown) along the beam path (however, offset from the original beamline axis due to the deflector 28) for implantation using the ribbon ion beam 14. Note that such an end station contemplates use of a batch system, wherein multiple workpieces are rotated past the ribbon beam, or a single workpiece end station, wherein a single workpiece is scanned past the ribbon beam or the ribbon beam is scanned across the workpiece, respectively.

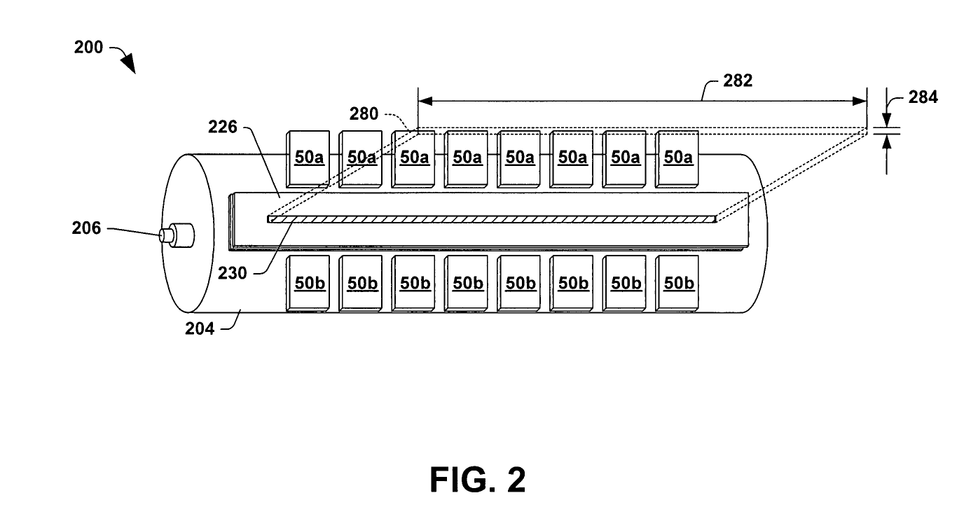

Turning now to FIG. 2, an exemplary ion source 200 is illustrated in simplified form that can be utilized in accordance with the present invention. It is appreciated that certain details such as the power sources and control systems are not shown for the sake of clarity and brevity. Additionally, it is also appreciated that other suitable ion sources that generate ribbon beam(s) can be employed in accordance with the present invention. The source 200 provides an elongated ribbon-shaped beam 280 having a length 282 and a width 284, with a large aspect ratio. The beam 280 of the present example is segmented into 8 portions or slices by virtue of the 8 magnet pairs 50a, 50b of a control apparatus, whereby the density profile of the beam 280 may be tailored to a specific application. In one implementation, the beam length 282 is about 400 mm, so as to facilitate single-scan implantation of 300 mm wafer targets or flat panel displays. However, any suitable desired beam length 282 can be generated. Moreover, any suitable desired width 284 can also be achieved, by appropriate sizing of an exit opening in a source housing 204, and the slits 230 of the extraction electrodes 226. Furthermore, it is noted that the extraction electrodes 226 may be implemented in an appropriate fashion, having other than five such electrodes 226, and that the illustrated electrodes 226 are not necessarily drawn to scale.

As will be discussed in greater detail infra, the extraction electrodes may be employed in conjunction with control circuitry to be biased at differing potentials based on the desired dopant species being employed. For example, if a p-type dopant is needed for implantation, a boron-containing source gas may be employed and the extraction electrodes are configured with a predetermined set of potentials applied thereto by the control circuit such that the energy of the extracted boron ions is at a predetermined level for proper mass analysis thereof. Similarly, if an n-type dopant is needed for implantation, an arsenic-containing source gas may be employed. In such an event, the control circuit configures the extraction electrodes at differing voltages such that the resultant extracted beam energy is at a different predetermined level for proper mass analysis thereof. As will be further appreciated, since the mass analyzer employs permanent magnets, the magnetic field strength therein is substantially constant, and tuning the mass analysis system for different type dopants is performed by varying the beam energy entering the mass analyzer via the extraction electrodes.

In general, the ion source 200 includes a conductive element 206 coaxial with the source chamber 204. RF energy supplied to the element 206 causes electric fields that energize charged particles therein. The accelerated charged particles collide with source gas atoms introduced into the chamber, causing ionization thereof and a plasma to form therein. The ions are then extracted from the chamber 204 via the extraction electrodes 226.

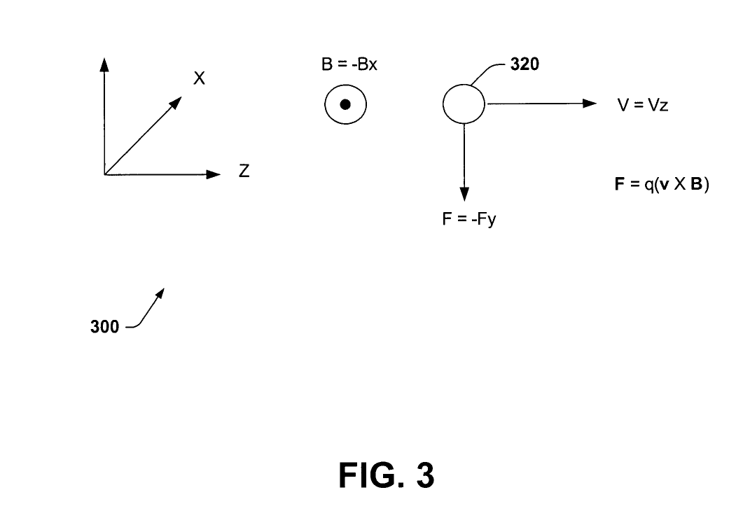

FIG. 3 is a diagram illustrating the affect of a magnetic field on a beam of charged ions/dopants traveling with a given velocity. Generally, a magnetic field serves to deflect ions in the beam in accordance with the Lorentz force equation: F=q(v×B), wherein a charge moving with a velocity in a direction indicated by the velocity vector v in the presence of a magnetic field oriented as indicated by the magnetic field vector B is a value having a direction indicated by the force vector F. More particularly, as illustrated in FIG. 3, if the ion 320 in the beam is positively charged and moving with velocity V in the Z direction, and a magnetic field is oriented in the X direction perpendicular to the direction of travel, a force is exerted on the ion in the negative Y direction, or in this example, downwards as illustrated.

Since the magnetic field for a mass analyzer of the present invention serves to deflect ions in the beam, it is desirable for the magnetic field to be as uniform as possible across the beam, and particularly across the entire width of the beam when employing a ribbon or ribbon-like beam. In one exemplary application where the ribbon beam is scanned across a 300 mm semiconductor wafer, the ribbon beam is greater than 300 mm wide, and thus it is desirable that the magnetic field be uniform over a distance that is substantially greater than the ribbon width to minimize distortion at edges of the ribbon beam. Generally, it is difficult to employ an electromagnet that generates a suitably uniform magnetic field over such a distance because of cost, complexity, bulk, power, and the like required by such a magnet. Accordingly, the present invention employs permanent magnets to generate a suitably uniform magnetic field.

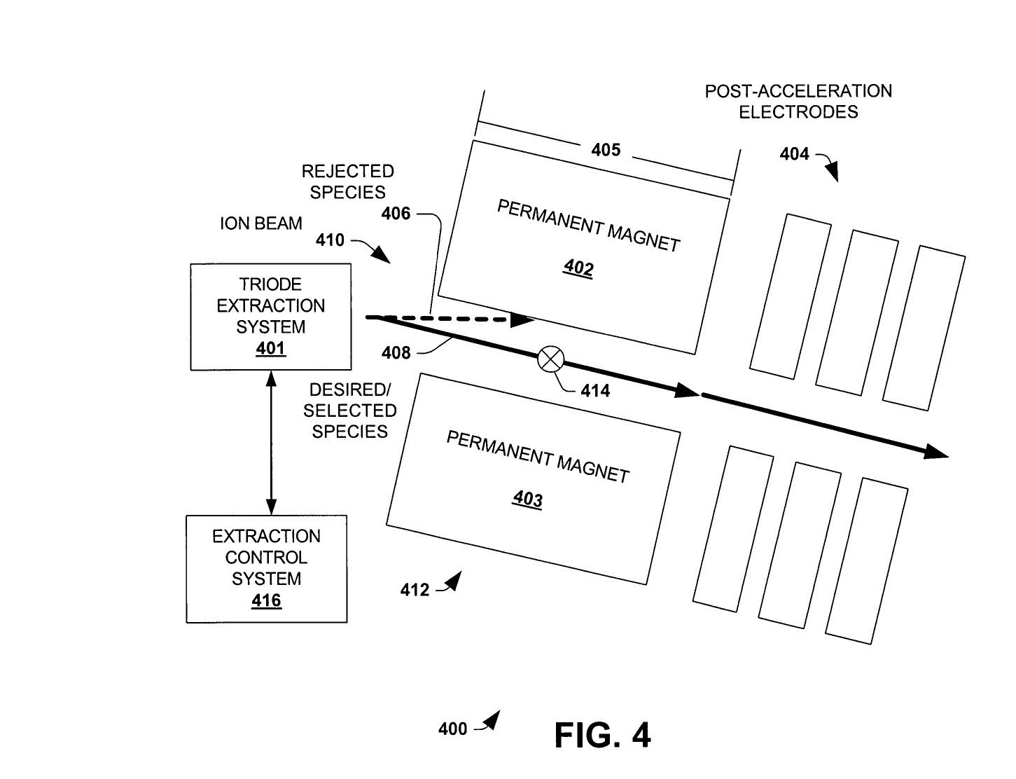

Turning now to FIG. 4, a diagram illustrating a ribbon beam extraction with mass analysis system 400 is depicted in accordance with an aspect of the present invention. The system 400 employs permanent magnets that provide a suitably uniform magnetic field within the beam path, which selects desired ions having a predetermined charge-to-mass ratio for a given energy from an ion beam.

An ion source (not shown) generates ions for a number of species by utilizing, for example, a plasma source and a power source. The species can include, for example, positive boron ions (B+) and positive fluoride ions (F+), positive phosphorous ions (P+) and positive hydrogen ions (H+), and the like. The ion source includes any suitable input gas that can generate the selected species including, but not limited to, arsenate (As₅), boron triflouride (BF₃), phosphorous pentaflouride (PF₅), diborane (B₂H₆), phosphine (PH₃), arsine (AsH₃), and the like. It is noted that conventional ribbon type ion implantations are generally limited to hydrogen containing gases such as diborane (B₂H₆), phosphine (PH₃), and arsine (AsH₃) because they lack the mass analyzer of the present invention. The selection of source gas and power source at least partially determine the species generated by the ion source. A triode extraction system 401 extracts the selected species from the ion source and accelerates them towards a mass analyzer 412 as an ion beam 410. The ion beam 410 is a ribbon type beam that has a width that is relatively large. An exemplary width for the ion beam 410 is about 400 mm (enough to cover a wafer in a single pass). The energy of extracted ions can vary by implementation, but is generally relatively low (e.g., 500 keV). It is appreciated that the present invention includes other ions/dopants and/or other energy values.

A mass analyzer 412 then operates on the ion beam 410 to remove rejected species 406 while keeping desired/selected species 408 within the ion beam 410. Additionally, the mass analyzer can remove other unwanted contaminants, such as hydrogen, from the beam. The removal of such contaminants can lead to substantial or significant power savings. For example, a conventional ribbon beam type ion system can have as much of 90 percent of an ion beam comprising hydrogen thereby wasting considerable power. Note that to the extent that the terms unwanted dopant/species are used herein, such terms are meant to include ions of one species that have an undesired charge-to-mass ratio for a given energy, or ions of undesired species such as hydrogen or other element employed in the initial source gas. In addition, although a desired species is referred to herein as an ion with a desired charge-to-mass ratio, it should be understood that such ratio assumes a given ion energy. In other words, the mass analyzer 412 selects ions to pass therethrough that have a predetermined mass energy product.

The mass analyzer 412 comprises a first permanent magnet 402 and a second permanent magnet 403 disposed along an expected path of the ion beam 410, opposite one another. The magnets 402 and 403 are oriented about the ion beam's 410 short dimension to provide a desired, substantially uniform magnetic field 414 across a widest portion of the ion beam 410 that selectively removes the rejected species 406 and contaminants from the ion beam 410. The length 405 of the magnetic field through which the ion beam 410 passes is relatively short (e.g., about 5 cm) and is also referred to as a drift region. The magnitude of the magnetic field is a function of the size and composition of the permanent magnets 402 and 403. Permanent magnets, as opposed to electromagnets, generally provide a substantially constant magnetic field. Additionally, the direction and orientation of the magnetic field 414 is a function of the position and orientation of the magnets 402 and 403. Here, the magnetic field 414 is depicted as going into the page. The magnets 402 and 403 are depicted as being rectangular in shape, but can be and often are curved so as to provide for a curved ion beam path.

Unlike electromagnet based mass analyzers, the magnetic fields generated by the permanent magnets cannot be altered. An extraction control system 416 controls the triode extraction system 401 and allows for different ion selection by adjusting the energy or velocity with which ions exit the ion source and enter the mass analyzer 412. The control system 416 can be employed to adjust electrodes (e.g., alter an applied voltage to one or more electrodes associated therewith) within the triode extraction system 401 to achieve the appropriate energy for the ions.

After processing by the mass analyzer 412, the ion beam 410 travels through post-acceleration electrodes 404. The electrodes 404 accelerate or decelerate ions/dopants remaining in the ion beam 410 to a desired/selected energy level. Individual electrodes are biased to selected voltages such that an electric field is applied tangentially across the ion beam path. The polarity of the field as well as the polarity of the ions within the ion beam determine whether acceleration or deceleration is performed. Subsequently, the ion beam 410 is directed/deflected towards one or more wafers at an end station thereby performing the ion implant with the desired species 408 and energy. The energy of ions can vary by implementation, however typical energy values for boron are about 1 to 10 keV and typical energy values for arsenic are about 1.5 keV.

It is appreciated that suitable variations in components are contemplated in accordance with the present invention so long as the mass analyzer employs permanent magnets to select one or more species and remove undesired species and contaminants from the ion beam. For example, the triode extraction system 401 can be configured as part of an ion source. As another example, the mass analyzer 412 can be integrated with the triode extraction system 401.

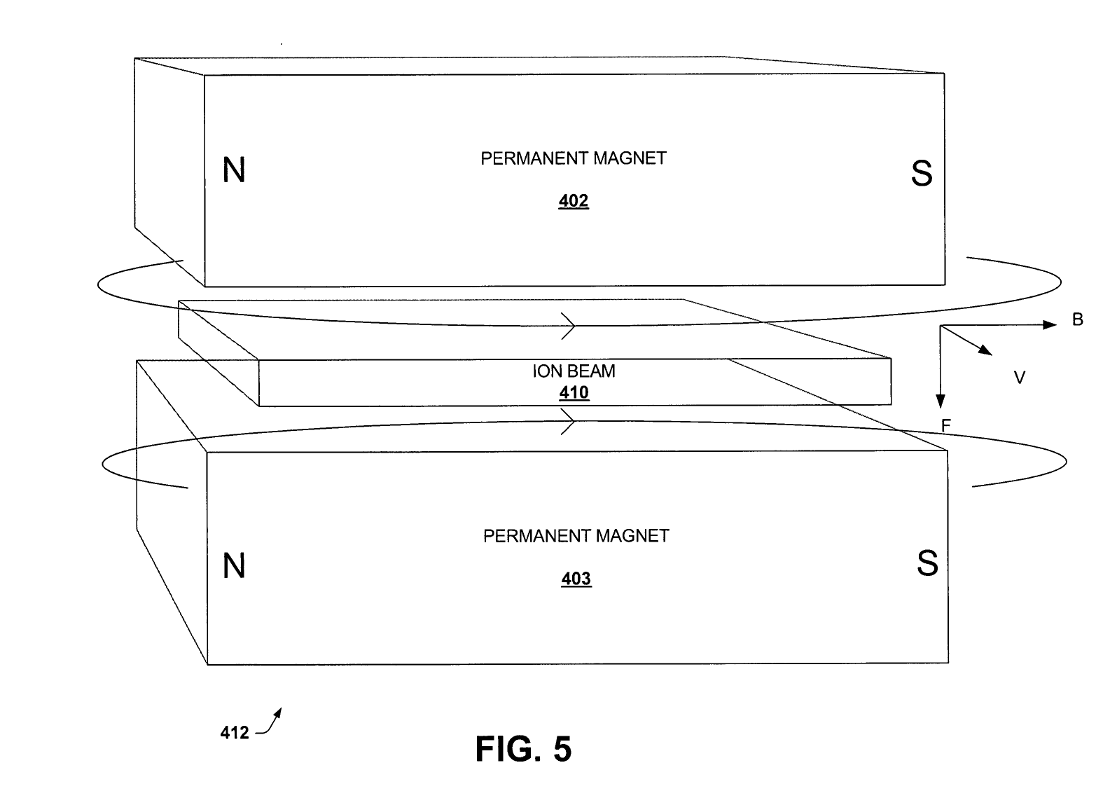

Continuing on with FIG. 5, a view of the mass analyzer 412 from FIG. 4 is provided in accordance with an aspect of the present invention. This view depicts the ion beam 410 traveling between the first permanent magnet 402 and the second permanent magnet 403. Particles within the ion beam 410 are traveling (due to their energy) with a velocity v in the indicated direction (out of the page). The permanent magnets 402 and 403 are arranged with their poles so as to provide a substantially uniform magnetic field B in the indicated direction (right). It is appreciated that, as discussed supra, a magnetic field serves to deflect ions in the beam in accordance with the Lorentz force equation: F=q(v×B), wherein a charge moving with a velocity in a direction indicated by the velocity vector v in the presence of a magnetic field oriented as indicated by the magnetic field vector B is a value having a direction indicated by the force vector F. As a result and assuming that the particles (dopants/ions) are positively charged, a force F is exerted on the particles in a downward direction as indicated. The magnitude of the force F depends on the strength of the magnetic fields B.

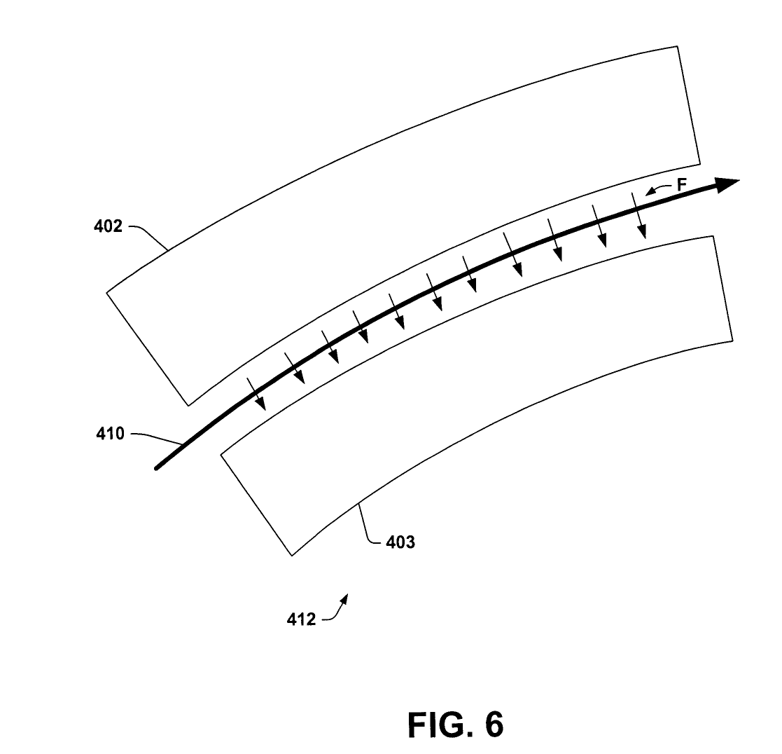

FIG. 6 is another view of the mass analyzer 412 that illustrates a curved path on which the ion beam 410 travels in accordance with an aspect of the present invention. Here, the magnets 402 and 403 are depicted with a slight curvature. This curvature is provided to compensate for bending of the ion beam 410 as it travels through the magnetic field B and undergoes the force F. Ions/particles that have the selected/desired mass (or mass-energy product) travel through the mass analyzer 412 without impacting either magnet. Particles/ions that have greater mass (or mass-energy product) that that of the selected species tend to impact the first permanent magnet 402 whereas articles that have less mass (or mass-energy product) than that of the selected species tend to impact the second permanent magnet 403, thereby removing unwanted species and/or contaminants.

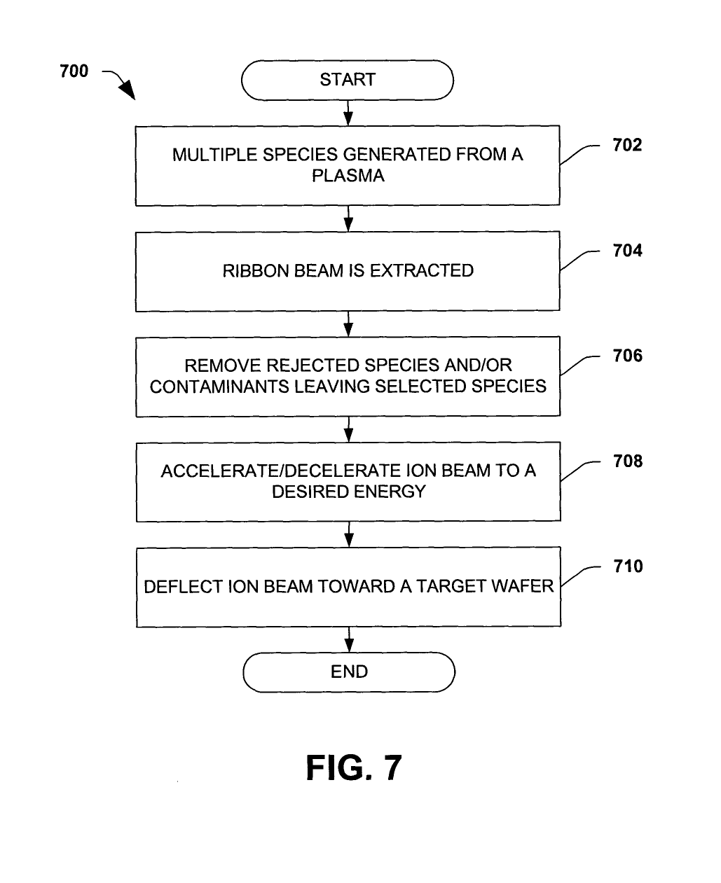

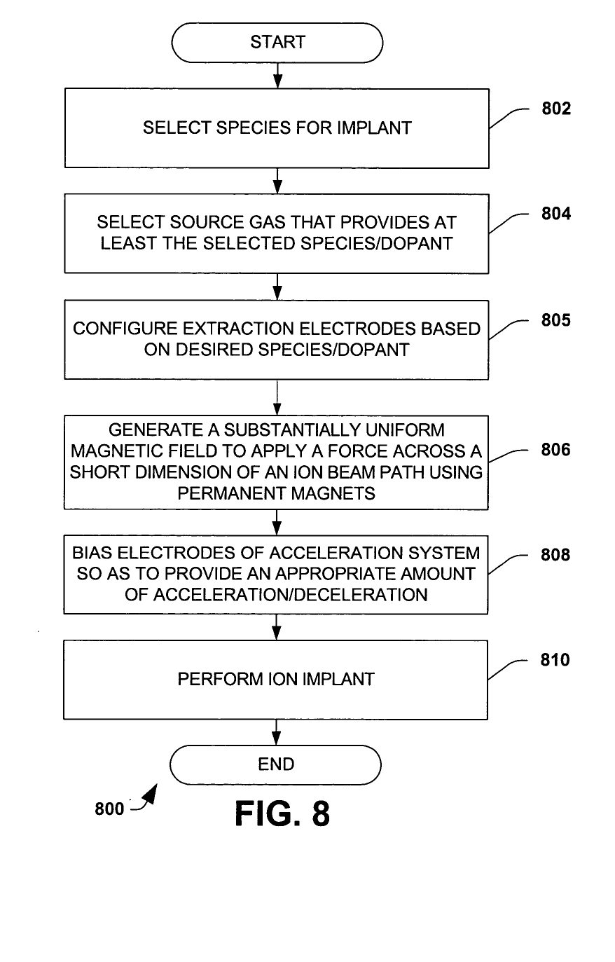

In view of the foregoing structural and functional features described supra and infra, methodologies in accordance with various aspects of the present invention will be better appreciated with reference to FIGS. 1-6. While, for purposes of simplicity of explanation, the methodologies of FIGS. 7-8 are depicted and described as executing serially, it is to be understood and appreciated that the present invention is not limited by the illustrated order, as some aspects could, in accordance with the present invention, occur in different orders and/or concurrently with other aspects from that depicted and described herein. Moreover, not all illustrated features may be required to implement a methodology in accordance with an aspect the present invention.

FIG. 7 is a flow diagram illustrating a method 700 of generating a ribbon type ion beam in accordance with an aspect of the present invention. The method 700 is operable to select ions of a predetermined charge-to-mass ratio for a given energy to generate a ribbon type ion beam.

The method 700 begins at block 702, wherein an ion beam comprised of multiple species is generated from a selected input source gas and a power source. The ion source comprises a plurality of species and/or contaminants. At block 704, a ribbon ion beam is generated/extracted from the ion source. An extraction system, such as a triode extraction system, is employed to extract the ions and form the ion beam with a ribbon shape (e.g., wherein a wide dimension is substantially longer than a short dimension). Additionally, the ion beam is formed such that the particles within are nearly parallel to each other.

Rejected species and/or contaminants are removed from the ion beam leaving a selected/desired species at block 706 via a permanent magnet based mass analyzer. Physically, the mass analyzer can be part of the extraction system. The mass analyzer comprises a pair of permanent magnets disposed opposite each other and configured so as to provide a substantially uniform magnetic field of a selected magnitude and direction across a path of the ribbon ion beam. As particles within the ion beam pass between the magnets and through the magnetic field, the magnetic field results in a force being applied to the particles. Particles that are outside of a selected range of mass-to-charge ratio for a given energy (which matches that of the selected species) tend to diverge from the ion beam path and impact one of the magnets or another barrier. As a result, the selected species, which have a mass within the selected range, travel substantially along the ion beam path and through the mass analyzer.

At block 708, the ion beam is accelerated or decelerated to a desired or selected energy via an acceleration system. The system comprises a number of electrodes biased to selected voltages so as to generate electric fields that accelerate or decelerate the particles within the ion beam. Continuing, the ion beam is deflected toward a target wafer at an end station at block 710. A deflection system, such as described supra, is typically employed to appropriately direct the ion beam. The ion beam can then be employed to perform ion implantation on one or more wafers. Typically, the generated ion beam has a width and aspect ratio that permits performing a desired implant in a single pass. For example, the width of the ion beam could be greater than 300 mm for a 300 mm diameter wafer.

FIG. 8 is a method 800 of configuring a ribbon beam ion implantation system for a particular implant in accordance with an aspect of the present invention. The method 800 serves to illustrate that the permanent magnet based mass analyzer of the present invention allows a greater choice in source materials than do similar conventional systems that do not employ such a mass analyzer.

The method 800 begins at block 802 wherein a species/dopant, energy, and angle of implant for an ion implant are selected. Additionally, a selected width and aspect ratio for the ribbon beam to be generated are also selected or determined. An input gas is selected that at least provides the selected dopant as well as one or more other species at block 804. At 805, the extraction electrodes associated with the ion source are configured based on the desired species/dopant. For example, if the desired dopant is a p-type dopant such as boron, that information is employed to bias the extraction electrodes at a predetermined set of potentials so that the extracted ions have a predetermined energy for entry into a mass analyzer.

A mass analyzer that employs permanent magnets as discussed supra is configured to generate a selected magnetic field and therefore apply a selected amount of force across ion beams that pass therethrough at block 806. Additionally, the mass analyzer can be rotated and/or repositioned such that the selected dopant/species can pass through the mass analyzer. Since the mass analyzer has a substantially fixed magnetic field, the energy of the incoming ions dictates the tuning of the system since the mass-energy product of the system is constant. Next, electrodes of an acceleration system are biased at block 808 to voltages so as to provide an appropriate amount of acceleration or deceleration to particles within the ion beam so as to attain the desired energy for the implant. Finally, the ion implantation is performed at block 810 substantially at the selected energy, angle of implant and with the selected dopant.

It is noted that the permanent magnet produces a constant, uniform magnetic field in the gap, and thus unlike electromagnetic type mass analyzers, tuning the analyzer to select different species or ions is not achieved by altering the magnetic field strength. Instead, since the mass-energy product for the system is constant, to get ions of a desired mass, the energy at which ions are extracted from the ion source is changed to effectuate tuning of the mass analysis system.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising.”

1. A ribbon beam ion implantation system comprising:
an ion source operable to generate multiple ion species from a source material;
an extraction system configured to extract the ion species from the ion source and generate a ribbon-shaped ion beam; and
a mass analyzer comprised of a first permanent magnet and a second permanent magnet that generates a substantially uniform magnetic field across a beam path of the ribbon-shaped ion beam to select a species from the multiple species initially present in the ribbon-shaped ion beam.

2. The system of claim 1, further comprising an acceleration system aligned along the beam path that operates on the ion beam after the mass analyzer and accelerates or decelerates the ion beam to a predetermined implantation energy level.

3. The system of claim 1, wherein the extraction system is a triode extraction system operative to produce a converging beam.

4. The system of claim 1, wherein the ion beam extracted by the extraction system is at a relatively low energy.

5. The system of claim 4, wherein the relatively low energy is about 500 eV.

6. The system of claim 1, wherein the magnetic field generated by the mass analyzer has a length of about 5 cm through which the ion beam travels.

7. The system of claim 1, wherein the magnetic field is oriented along the ribbon-shaped ion beam's short dimension.

8. The system of claim 1, wherein the magnetic field is relatively high with rapidly decaying fringes.

9. The system of claim 1, wherein the multiple species include B+, F+, BF1+ and BF2+, and the selected species is B+ or BF2+.

10. The system of claim 1, wherein the multiple species include P+ and H+ and the selected species is P+.

11. The system of claim 1, wherein the source material comprises boron trifluoride (BF3).

12. The system of claim 1, wherein the source material comprises phosphorous pentafluoride (PF5).

13. The system of claim 1, wherein the source material comprises arsenate (As5).

14. The system of claim 1, wherein the ion beam has a width of about 300 mm.

15. The system of claim 1, further comprising an end station having a wafer, wherein the ion beam is operative to implant the selected species on the wafer in a single pass.

16. The system of claim 1, wherein the extraction system comprises a control circuit operable to receive one or more inputs indicative of a desired ion species, and output a set of predetermined voltages for electrodes associated with the extraction system based on the one or more inputs.

17. The system of claim 16, wherein the set of predetermined voltages dictates an extraction energy of the ribbon-shaped ion beam entering the mass analyzer.

18. A mass analyzer system that selects and removes species from a ribbon-shaped ion beam comprising:
a first permanent magnet located above a ribbon beam path;
a second permanent magnet located below the ribbon beam path, wherein the first permanent magnet and the second permanent magnet are oriented so as to deflect a passing ribbon-shaped ion beam across its short dimension; and
an extraction system associated with a ribbon-shaped ion source, operable to extract a ribbon-shaped ion beam therefrom at a plurality of different energies, wherein an energy of the extracted ribbon-shaped ion beam is a function of a desired dopant species.

19. The mass analyzer system of claim 18, wherein the first permanent magnet and the second permanent magnet have a slight curvature to match the ribbon beam path.

20. The mass analyzer system of claim 19, wherein the extraction system comprises a control circuit operable to receive one or more inputs indicative of a desired ion species, and output a set of predetermined voltages for extraction electrodes associated with the extraction system based on the one or more inputs.

21. A method of generating a ribbon type ion beam comprising:
generating multiple ion species from an ion source;
extracting the multiple ion species to form a ribbon-shaped ion beam having a short dimension and a wide dimension, wherein the wide dimension is substantially larger than the short dimension; and
selecting a species and rejecting other species of the multiple species of the ion beam via a permanent magnet based mass analyzer.

22. The method of claim 21, further comprising accelerating/decelerating the ion beam to a desired energy level after selecting the species.

23. The method of claim 21, further comprising directing the ion beam towards a target wafer at an end station.

24. The method of claim 23, further comprising performing an ion implant on the target wafer with the ion beam in a single pass, wherein the target wafer has a diameter of about 300 mm and the wide dimension of the ion beam is greater than about 300 mm.

25. The method of claim 21, wherein the species is selected by applying a magnetic field via permanent magnets that deflects the ion beam across its short dimension.

26. The method of claim 21, wherein extracting the multiple ion species comprises:
identifying the selected species; and
configuring extraction electrodes with a set of predetermined voltages such that the extracted ribbon-shaped ion beam has an energy that is a function of the identified selected species.
